(19) United States
(12) Patent Application Publication
(10) Pub. No.: US 2026/0018510 A1
(43) Pub. Date: Jan. 15, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Yannik Loris Wilfried JUNK, Hsinchu (TW); Hung-Li CHIANG, Taipei City (TW); Jer-Fu WANG, Taipei City (TW); Iuliana RADU, Hsinchu County (TW)

(73) Assignee: TAIWAN SEMICONDUCTOR MANUFACTURING COMPANY, LTD., Hsinchu (TW)

(21) Appl. No.: 18/769,575

(22) Filed: Jul. 11, 2024

(51) Int. Cl. H01L 23/522; H01L 21/8234; H01L 23/528; H01L 27/088; H01L 29/06; H01L 29/08; H01L 29/417; H01L 29/423; H01L 29/66; H01L 29/775; H01L 29/786

(52) U.S. Cl. CPC H01L 23/5226; H01L 23/5283; H10D 30/014; H10D 30/43; H10D 30/6729; H10D 30/6735; H10D 30/6757; H10D 62/121; H10D 62/151; H10D 84/013; H10D 84/0149; H10D 84/038; H10D 84/83

(57) ABSTRACT

The present disclosure provides a semiconductor device. The semiconductor device includes a substrate and a transistor in the substrate. The transistor includes a gate structure penetrating through the substrate, a first source/drain region at a front side of the substrate, and a second source/drain region at a back side of the substrate.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a semiconductor device in accordance with some embodiments of the present disclosure.

FIGS. 1B and 1C are cross-sectional views of a semiconductor device in accordance with some embodiments of the present disclosure.

FIG. 1D is a simulation result of a semiconductor device in accordance with some embodiments of the present disclosure.

FIGS. 2 to 14 illustrate a method in various stages of forming a semiconductor device in accordance with some embodiments of the present disclosure.

FIG. 15 is a cross-sectional view of a semiconductor device in accordance with some embodiments of the present disclosure.

FIG. 16 is a cross-sectional view of a semiconductor device in accordance with some embodiments of the present disclosure.

FIG. 17 is a cross-sectional view of a semiconductor device in accordance with some embodiments of the present disclosure.

FIGS. 18 to 21 illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

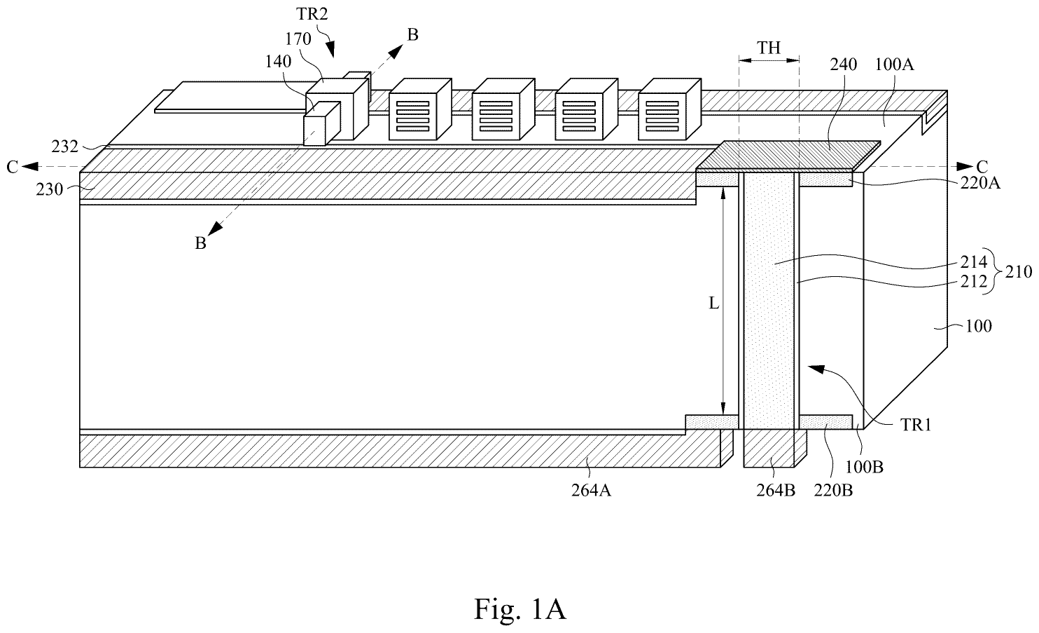

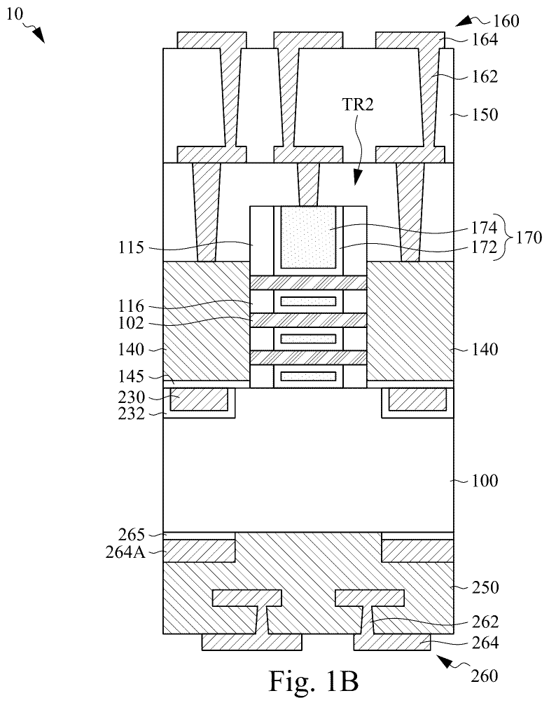

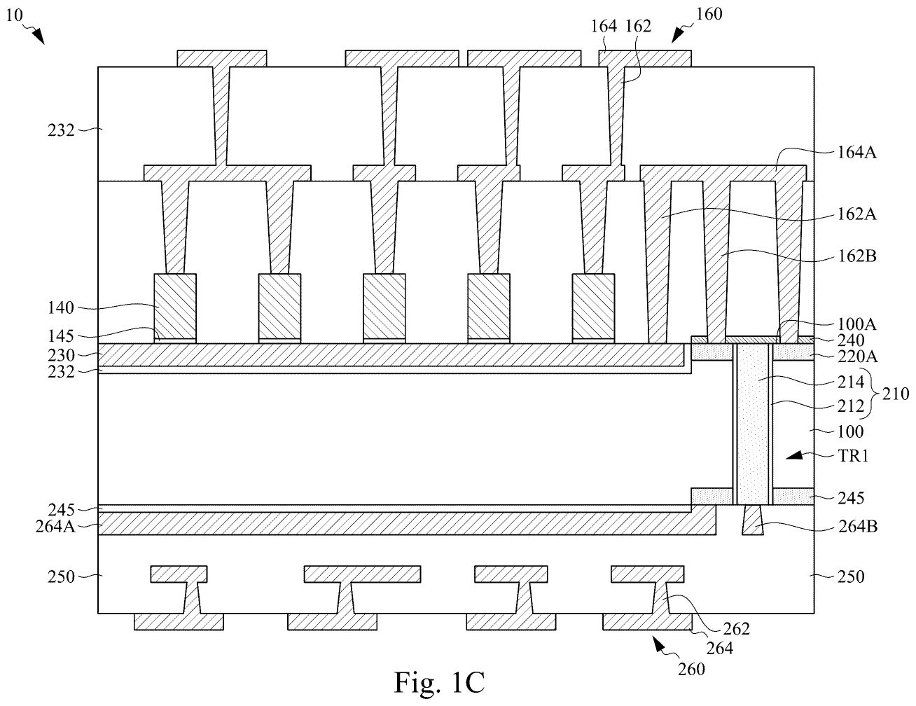

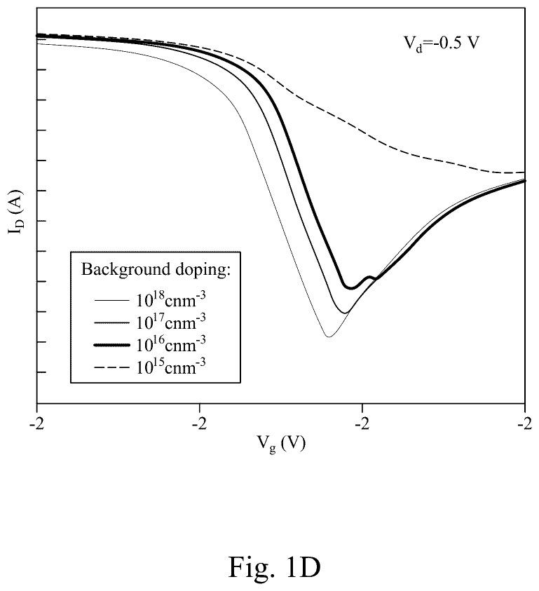

FIG. 1A is a schematic view of a semiconductor device in accordance with some embodiments of the present disclosure. FIGS. 1B and 1C are cross-sectional views of a semiconductor device in accordance with some embodiments of the present disclosure. In greater detail, FIGS. 1B and 1C are cross-sectional views along lines B-B and C-C of FIG. 1A. It is noted that some elements of FIGS. 1B and 1C are not illustrated in FIG. 1A for brevity.

Shown there is a semiconductor device 10. The semiconductor device 10 includes a substrate 100. The substrate 100 generally include crystalline semiconductor material, such as silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The substrate 100 may be doped or un-doped. In some embodiments, when the substrate 100 is a p-type substrate, the p-type dopants may include boron (B), gallium (Ga), indium (In), aluminium (Al), or the like. On the other hand, if the substrate 100 is an n-type substrate, the n-type dopants may include phosphorus (P), arsenic (As), or antimony (Sb), or the like. The substrate 100 may include a first side 100A and a second side 100B opposite to the first side 100A. In some embodiments, the first side 100A and the second side 100B of the substrate 100 may also be referred to as the front side and the back side of the substrate 100, respectively.

The semiconductor device 10 includes at least one transistor TR1, which is formed penetrating through the substrate 100. In greater detail, the transistor TR1 includes a gate structure 210 and source/drain regions 220A and 220B on opposite ends of the gate structure 210. In greater detail, the gate structure 210 may vertically extend through the substrate 100 from the first side 100A of the substrate 100 to the second side 100B of the substrate 100. In some embodiments, the gate structure 210 may include a cylindrical top profile, while the disclosure is not limited thereto.

The source/drain region 220A is at the first side 100A of the substrate 100 and laterally surrounding the gate structure 210, and the source/drain region 220B is at the second side 100B of the substrate 100 and laterally surrounding the gate structure 210.

In some embodiments, the gate structure 210 includes a gate electrode 214 and a gate dielectric layer 212 laterally surrounding the gate electrode 214. In the cross-sectional view of FIG. 1C, the gate dielectric layer 212 has two vertical portions lining opposite sidewalls of the gate electrode 214. In some embodiments, the gate electrode 214 may be a via structure extending through a silicon substrate 100, and thus the gate electrode 214 may also be referred to as a through-silicon-via (TSV). In some embodiments, the source/drain regions 220A and 220B may be in contact with the gate dielectric layer 212, and may be separated from the gate electrode 214 through the gate dielectric layer 212. In some embodiments, the transistor TR1 may also be referred to as a through-silicon transistor.

In some embodiments, the gate dielectric layer 212 may include suitable dielectric material, such as silicon oxide (SiO₂), aluminum oxide (Al₂O₃), or the like. In other embodiments, the gate dielectric layer 212 may also include high-k dielectric material. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate electrode 214 may include a conductive material, such as copper (Cu), tungsten (W), titanium (Ti), aluminum (Al), the like, or combinations thereof.

With respect to the source/drain regions 220A and 220B, the source/drain regions 220A and 220B may be doped regions in the substrate 100. In some embodiments, the source/drain regions 220A and 220B both may be p-type doped region, or may be n-type doped regions. In some embodiments, the source/drain regions 220A and 220B may include different (or opposite) conductivity types than the substrate 100. For example, if the substrate 100 is a p-type substrate, the source/drain regions 220A and 220B may be n-type dope regions. Similarly, if the substrate 100 is an n-type substrate, the source/drain regions 220A and 220B may be p-type doped regions. In some embodiments, portions of the substrate 100 adjacent to the gate structure 210 and vertically between the source/drain regions 220A and 220B may serve as a channel region of the transistor TR1. That is, the carrier may flow between the source/drain regions 220A and 220B along a direction perpendicular to the top surface of the substrate 100. In some embodiments, the channel length L of the transistor TR1 is at a range from about 2 μm to about 8 μm (e.g., 5 μm). The lateral thickness of the gate structure 210 is in a range from about 150 nm to about 300 nm (e.g., 200 nm). In some embodiments, the vertical long channel may provide sufficient stability of the transistor TR1, and may not sacrifice the chip area, and thus such configuration may be beneficial for device shrinkage. In some embodiments, the dopant concentration of the source/drain regions 220A and 220B may be in a range from about 10¹⁵ cm⁻³ to about 10¹⁸ cm⁻³. In some embodiments, the dopant concentration of the source/drain regions 220A and 220B is higher than the dopant concentration of the substrate 100.

The semiconductor device 10 further includes a plurality of metal lines 230 embedded in the substrate 100. A dielectric liner 232 may line the surfaces of the metal lines 230, so as to electrically isolate the metal lines 230 from the substrate 100. In some embodiments, the metal lines 230 may include a conductive material, such as copper (Cu), tungsten (W), titanium (Ti), aluminum (Al), the like, or combinations thereof. The dielectric liner 232 may include silicon oxide (SiO₂), silicon nitride (SiN), silicon oxynitride (SiON), silicon oxycarbide (SiOC), silicon carbonitride (SiCN), the like, or combinations thereof. In some embodiments, at least one metal line 230 may be electrically connected to the source/drain region 220A of the transistor TR1, which will be discussed in more detail later.

The semiconductor device 10 further includes a dielectric cap 240 extending along the first side 100A of the substrate 100 and covering the source/drain region 220A and the gate structure 210 of the transistor TR1. In some embodiments, the dielectric cap 240 may be in contact with the source/drain region 220A, the gate dielectric layer 212, and the gate electrode 214.

The semiconductor device 10 further includes several transistors TR2 disposed over the substrate 100 and at a higher level than the transistor TR1. In some embodiments, the transistors TR2 are illustrated as having gate-all-around (GAA) configuration, while the disclosure is not limited thereto. In other embodiments, the transistors TR2 may also include various types of configurations, such as a planar transistor, a fin FET transistor, etc.

Reference is made to FIG. 1B, each transistor TR2 includes semiconductor channel layers 102 stacked one above another over the substrate 100, a gate structure 170 wrapping around each of the semiconductor channel layers 102, and source/drain epitaxial structures 140 on opposite ends of each semiconductor channel layer 102. In some embodiments, the semiconductor channel layers 102 may include silicon or other suitable semiconductor material. In some embodiments, carrier may flow in each semiconductor channel layer 102 and between the source/drain epitaxial structures 140 along a direction parallel to the top surface of the substrate 100.

The gate structure 170 may include a gate dielectric layer 172 and a gate electrode 174. In some embodiments, the gate dielectric layer 172 may include an interfacial layer and a high-k dielectric layer over the interfacial layer. The interfacial layer may be made of oxide, such as aluminum oxide (Al₂O₃), silicon oxide (SiO₂), or the like. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate electrode 174 may include work function metal layer(s) and a filling metal over the work function metal layer. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

Gate spacers 115 are disposed on opposite sides of the gate structure 170, and inner spacers 116 are disposed on opposite sides of the gate structure 170 and vertically between adjacent two semiconductor channel layers 102. In some embodiments, the gate spacers 115 and the inner spacers 116 may include silicon oxide, silicon nitride, silicon oxynitride, the like, or combinations thereof.

As shown in FIGS. 1A and 1B, the source/drain epitaxial structures 140 of the transistor TR2 may vertically overlap the metal lines 230, respectively In some embodiments, the semiconductor device 10 may further includes isolation layers 145 below the respective source/drain epitaxial structures 140, and may electrically isolate the source/drain epitaxial structures 140 from the metal lines 230. In some embodiments, the isolation layers 145 may be both in contact with the respective metal lines 230 and the respective source/drain epitaxial structures 140. However, in other embodiments, the isolation layers 145 may be omitted, such that the metal lines 230 may be in direct contact with the respective source/drain epitaxial structures 140 of the transistor TR2.

The semiconductor device 10 further includes an interlayer dielectric (ILD) layer 150 over the first side 100A of the substrate 100 and covering the transistors TR1 and TR2. In some embodiments, the ILD layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

An interconnect structure 160 is disposed in the ILD layer 150 and electrically connected to the transistors TR1 and TR2 according to a predetermined routing design. In some embodiments, the interconnect structure 160 may electrically connect the transistors TR1 and TR2. It is noted that the interconnect structure 160 is not illustrated in FIG. 1A for brevity. In some embodiments, the interconnect structure 160 includes a plurality of metal vias 162 and metal lines 164. Because the interconnect structure 160 is disposed at the front side (e.g., first side 100A) of the substrate 100, the interconnect structure 160 can also be referred to as a front side interconnect structure.

As shown in FIG. 1B, the interconnect structure 160 may be electrically connected to the gate structure 170 and the source/drain epitaxial structures 140 of the transistor TR2. As shown in FIG. 1C, the interconnect structure 160 may be electrically connected with the metal line 230 and the source/drain region 220A of the transistor TR1. For example, the interconnect structure 160 may include a metal via 162A in contact with the top surface of the metal line 230, at least one (e.g., 2 in the illustrated embodiments) metal via 162B in contact with the source/drain region 220A of the transistor TR1, and a metal line 164A in contact with the metal vias 162A and 162B. That is, the metal vias 162A and 162B and the metal line 164A of the interconnect structure 160 may electrically connect the source/drain region 220A of the transistor TR1 to the metal line 230. In some embodiments, the metal vias 162B may penetrate through the dielectric cap 240, so as to form physical contact with the source/drain region 220A of the transistor TR1.

The semiconductor device 10 further includes a dielectric layer 250 over the second side 100B of the substrate 100. In some embodiments, the dielectric layer 250 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

An interconnect structure 260 is disposed in the dielectric layer 250 and electrically connected to the transistor TR1 according to a predetermined routing design. In some embodiments, the interconnect structure 260 includes a plurality of metal vias 262 and metal lines 264. Because the interconnect structure 260 is disposed at the back side (e.g., second side 100B) of the substrate 100, the interconnect structure 260 can also be referred to as a back side interconnect structure.

As shown in FIG. 1C, the interconnect structure 260 may be electrically connected with the gate structure 210 and the source/drain region 220B of the transistor TR1. In greater detail, the interconnect structure 260 includes a metal line 264A extending along the second side 100B of the substrate 100 and in contact with the source/drain region 220B of the transistor TR1. The interconnect structure 260 further includes a gate contact 264B in contact with the gate electrode 214 of the gate structure 210. In some embodiments, the metal line 264A and the metal line 230 may be power rail, in which the transistor TR1 is electrically connected between the metal line 264A and the metal line 230, so as to provide power gating to the front side devices (e.g., transistors TR2).

The semiconductor device 10 further includes a dielectric layer 245 extending along the second side 100B of the substrate 100 vertically between the metal line 264A and the substrate 100, such that the dielectric layer 245 may electrically isolate the metal line 264A from the substrate 100. In some embodiments, the dielectric layer 245 may be in contact with only one side of the metal line 264A, while the dielectric liner 232 may be in contact more than one side (e.g., 3 in the illustrated embodiments) of the metal line 230. The dielectric layer 245 may include silicon oxide (SiO₂), silicon nitride (SiN), silicon oxynitride (SiON), silicon oxycarbide (SiOC), silicon carbonitride (SiCN), the like, or combinations thereof.

FIG. 1D is a simulation result of a semiconductor device in accordance with some embodiments of the present disclosure. In greater detail, FIG. 1D illustrates a simulation result of the semiconductor device 10 as discussed in FIGS. 1A to IC at different conditions. It can be seen that under the condition where drain voltage (Va) is −0.5V and the thickness of the gate dielectric layer 212 is about 1 nm, the gate voltage (VG) versus drain current (ID) plot of semiconductor device 10 shows transistor property when the dopant concentration of the source/drain regions 220A and 220B is about 10¹⁵ cm⁻³, 10¹⁶ cm⁻³, 10¹⁷ cm⁻³, and 10¹⁸ cm⁻³.

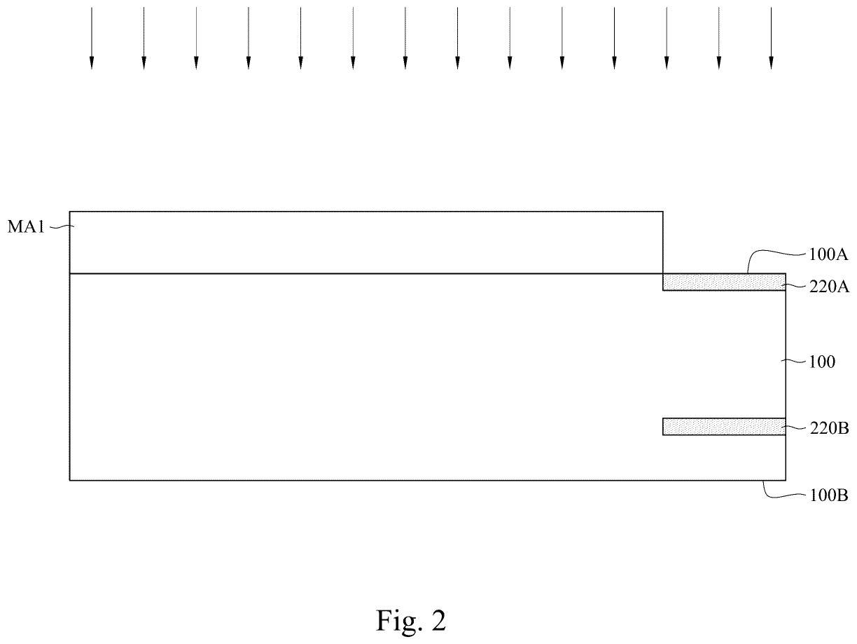

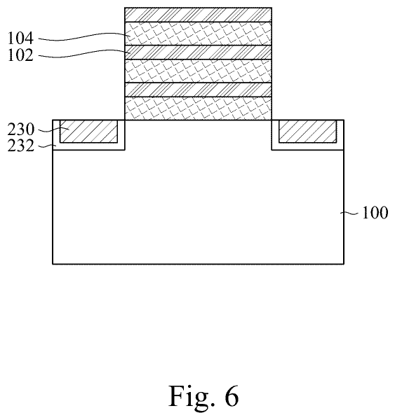

FIGS. 2 to 14 illustrate a method in various stages of forming a semiconductor device in accordance with some embodiments of the present disclosure. In greater detail, FIGS. 2 to 14 illustrate a method for forming the semiconductor device 10 as discussed above with respect to FIGS. 1A to IC. FIGS. 2, 3, 4, 5, 9B, 12B, 13, and 14 have a same cross-sectional view as FIG. 1C. FIGS. 6, 7, 8, 9A, 10, 11, and 12A have a same cross-sectional view as FIG. 1B. Although FIGS. 2 to 14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2 to 14 have been discussed above with respect to FIGS. 1A to IC, such elements are labeled the same, and relevant details will not be repeated for brevity.

Reference is made to FIG. 2. Shown there is a substrate 100. A patterned mask MA1 is formed over the substrate 100 and having an opening exposing a portion of the substrate 100. Afterwards, source/drain regions 220A and 220B are formed at different levels of the substrate 100 through the opening of the patterned mask MA1. In greater detail, the source/drain region 220A is formed at the first side 100A (e.g., front side) of the substrate 100, and the source/drain region 220A is formed at a level between the first side 100A and the second side 100B of the substrate 100.

In some embodiments, source/drain regions 220A and 220B may be formed through different implantation processes. For example, a first implantation process may be performed to dope the surface region of the substrate 100 to form the source/drain region 220A. A second implantation process may be performed to dope a region of the substrate 100 at a level between the first side 100A and the second side 100B of the substrate 100. In some embodiments, the second implantation process may be performed with a higher energy than the first implantation process, such that the dopants of the second implantation process may be driven deep into the substrate 100, such that the source/drain region 220B is at a level lower than the source/drain region 220A. In some embodiments, an annealing process is performed after the implantation processes are complete, so as to activate the source/drain regions 220A and 220B.

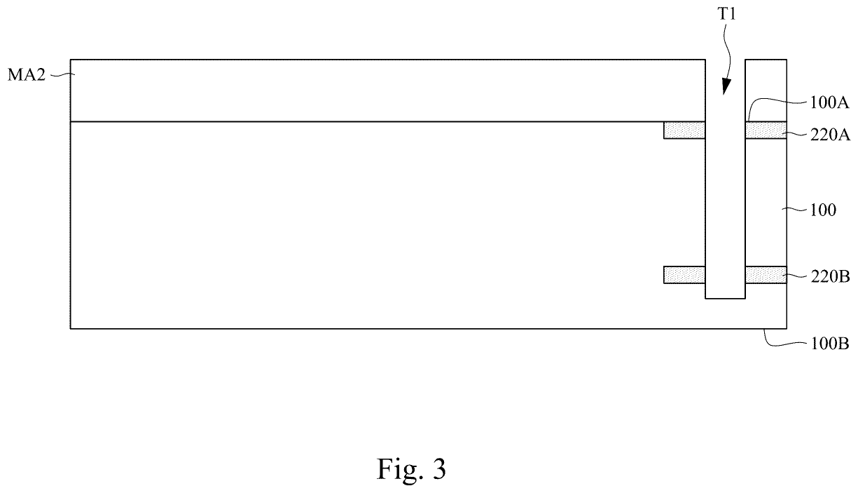

Reference is made to FIG. 3. Once the source/drain regions 220A and 220B are formed, the patterned mask MA1 is removed. Then, a patterned mask MA2 is formed over the substrate 100 and having an opening overlapping the source/drain regions 220A and 220B. Afterwards, an etching process is performed to etch the substrate 100 through the opening of the patterned mask MA2, so as to form a trench T1 in the substrate 100. In greater detail, the etching process may etch through the source/drain regions 220A and 220B. Moreover, the etching process is controlled such that the bottom end of the trench T1 is lower than the source/drain region 220B, and is higher than the second side 100B of the substrate 100.

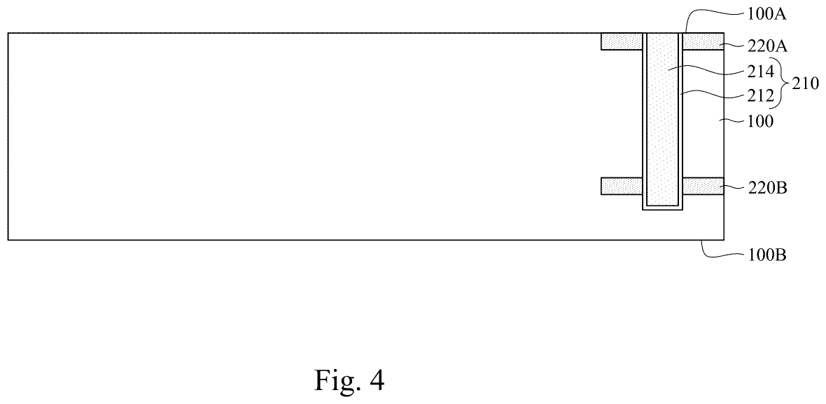

Reference is made to FIG. 4. Once the trench T1 is formed, the patterned mask MA2 is removed. Then, a gate structure 210 is formed in the trench T1. In some embodiments, the gate structure 210 may be formed by, for example, depositing a gate dielectric layer 212 lining the trench T1 in the substrate 100, depositing a gate electrode 214 over the gate dielectric layer 212 and overfilling the trench T1, followed by a planarization process, such as CMP to remove excess materials of the gate dielectric layer 212 and the gate electrode 214 until the top surface of the substrate 100 is exposed. Accordingly, the top surface of the gate electrode 214 and the top ends of the gate dielectric layer 212 may be substantially level with the top surface of the substrate 100. In some embodiments, the gate dielectric layer 212 may line the bottom surface of the gate dielectric layer 212.

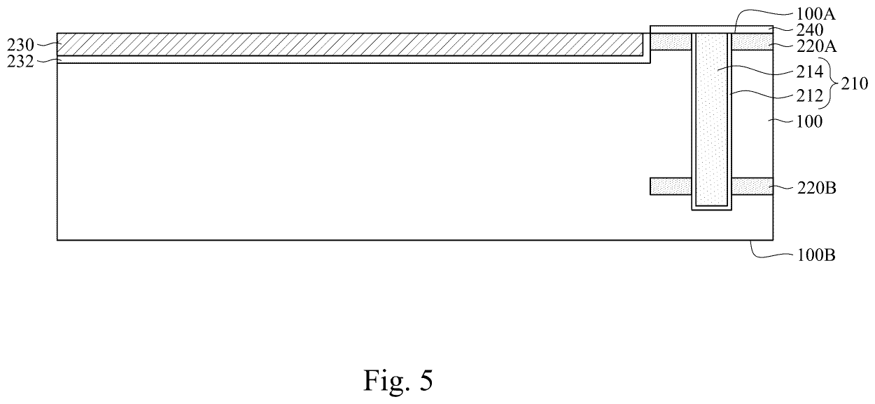

Reference is made to FIG. 5. Once the gate structure 210 is formed, a metal line 230 and a dielectric liner 232 are formed in the substrate 100, and a dielectric cap 240 is formed in contact with the top surface of the substrate 100 and covering the gate structure 210 and the source/drain region 220A. In some embodiments, the metal line 230 and the dielectric liner 232 may be formed by, for example, etching the substrate 100 to form a trench in the substrate 100, sequentially depositing a dielectric material and a conductive material in the trench of the substrate 100, and then performing a planarization process to remove excess materials of the dielectric material and the conductive material until the top surface of the substrate 100 is exposed. Accordingly, the top surface of the metal line 230 and the top ends of the dielectric liner 232 may be substantially level with the top surface of the substrate 100.

The dielectric cap 240 may be formed by, for example, depositing a dielectric layer over the substrate 100, and then patterning the dielectric layer to expose the metal line 230. In some embodiments, the metal line 230 and the dielectric liner 232 may be free of coverage by the dielectric cap 240.

Reference is made to FIG. 6. A stack of alternating semiconductor layers 102 and sacrificial layers 104 are formed over the substrate 100. In some embodiments, the semiconductor layers 102 may be made of pure silicon layers that are free of germanium. In some embodiments, the semiconductor layers 102 may also be substantially pure silicon layers, for example, with a germanium percentage lower than about 1 percent. The sacrificial layers 104 may be made of silicon germanium. For example, the germanium percentage (atomic percentage concentration) of the sacrificial layers 104 may be in a range from about 20 percent and about 60 percent. In some embodiments, the semiconductor layers 102, and the sacrificial layers 104 may be deposited using suitable deposition process, such as selective epitaxial growth (SEG), chemical vapor deposition (CVD), molecular beam epitaxy (MBE), or other suitable process(es). In some embodiments, the sacrificial layers 104 may be removed during a replacement gate (RPG) process. The sacrificial layers 104 may also be referred to as sacrificial semiconductor layers.

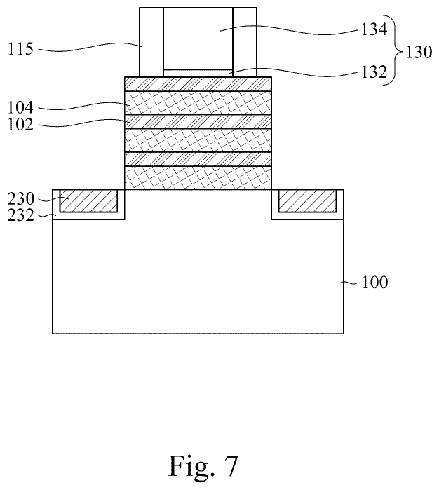

Reference is made to FIG. 7. A dummy gate structure 130 is formed over the substrate 100 and crossing the stack of the alternating semiconductor layers 102 and the sacrificial layers 104. In some embodiments, the dummy gate structure 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

Gate spacers 115 are formed on opposite sidewalls of the dummy gate structure 130. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structure 130. The spacer layer may be deposited using techniques such CVD, ALD, or the like.

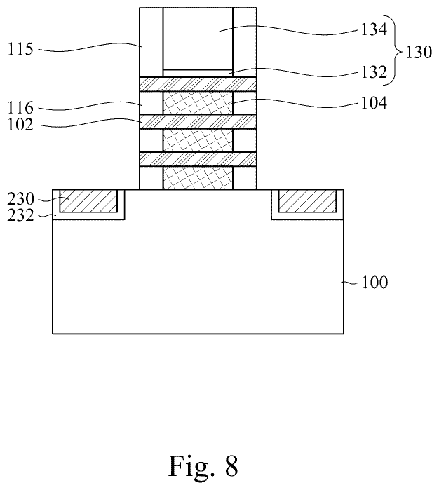

Reference is made to FIG. 8. An etching process is performed to remove portions of the semiconductor layers 102 and the sacrificial layers 104 by using the dummy gate structure 130 and the gate spacers 115 as etch mask. In some embodiments, the etching process may be wet etch, dry etch, or combinations thereof. The sacrificial layers 104 are laterally etched to form sidewall recesses. Afterwards, inner spacers 116 are formed in the sidewall recesses on opposite ends of each of the sacrificial layers 104.

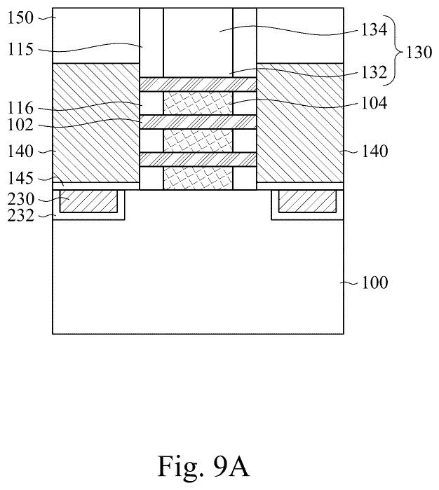

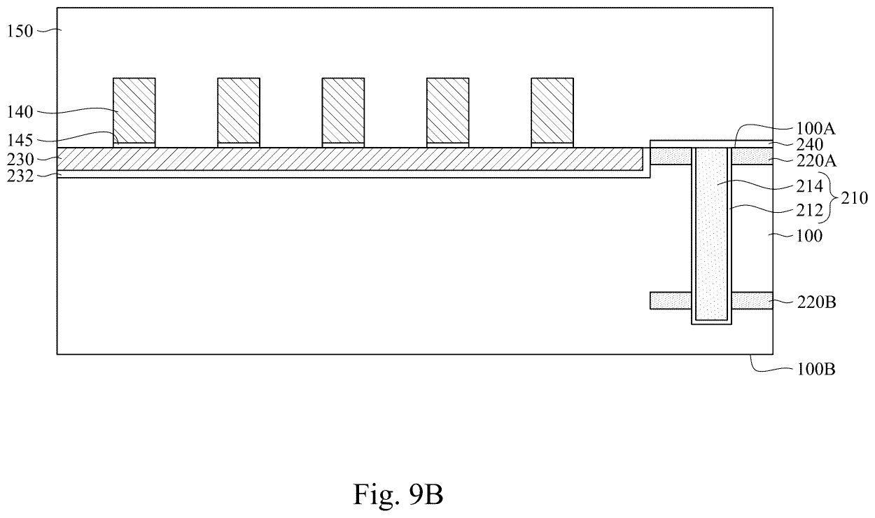

Reference is made to FIGS. 9A and 9B. Isolation layers 145 are formed over the substrate 100 and covering the metal lines 230. In some embodiments, the isolation layers 145 may be formed by, for example, depositing a dielectric material over the substrate 100, and then etching back the dielectric material.

After the isolation layers 145 are formed, source/drain epitaxial structures 140 are formed on opposite ends of each semiconductor layer 102, respectively. The source/drain epitaxial structures 140 may be formed by suitable deposition process, such as a selective epitaxial growth (SEG) process. In some embodiments, an implantation process may be performed to dope the source/drain epitaxial structures 140.

An interlayer dielectric (ILD) layer 150 is formed over the substrate 100 and covering the source/drain epitaxial structures 140. In some embodiments, the ILD layer 150 may be formed by, for example, depositing a dielectric material over the substrate 100, and then performing a planarization process to remove excess dielectric material until the dummy gate structure 130 is exposed. In some embodiments, as shown in FIG. 9B, the ILD layer 150 may also be formed in contact with the metal line 230 and the dielectric liner 232, and the dielectric cap 240.

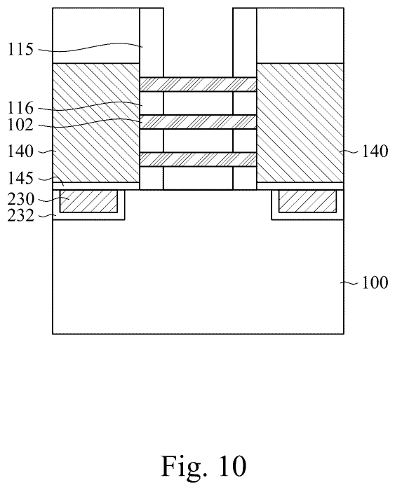

Reference is made to FIG. 10. The dummy gate structure 130 is removed to form gate trench between each pair of the gate spacers 115. Then, an etching process is performed to remove the sacrificial layers 104 through the gate trenches, such that the semiconductor layers 102 are suspended over the substrate 100.

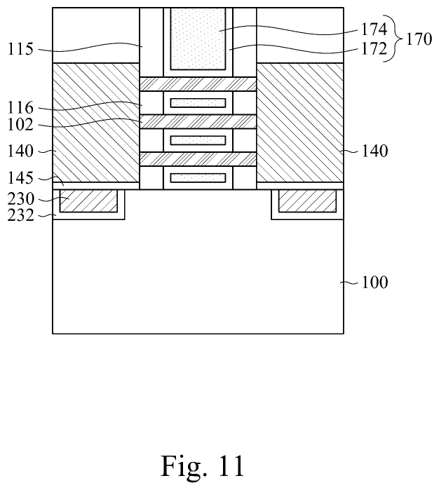

Reference is made to FIG. 11. Gate structure 170 is formed in the gate trench and wrapping around each of the semiconductor layers 102. In some embodiments, the gate structure 170 may be formed by, for example, sequentially depositing a gate dielectric layer 172 and a gate electrode 174 in the gate trench, and then performing a planarization process to remove excess materials of the gate dielectric layer 172 and the gate electrode 174 until the ILD layer 150 is exposed.

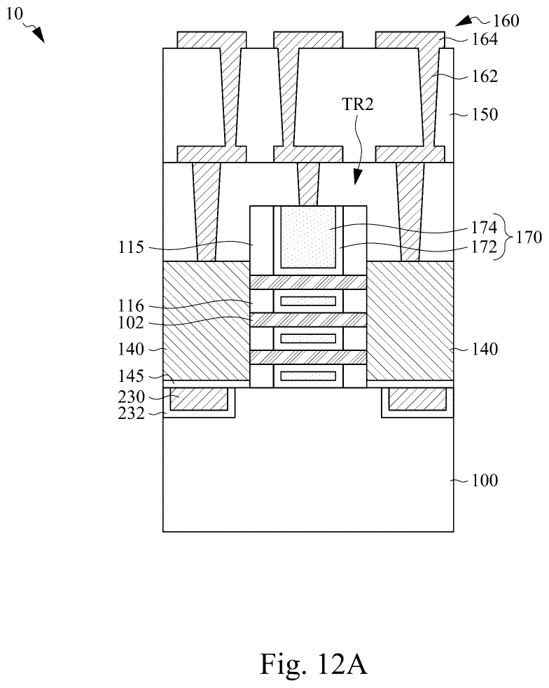

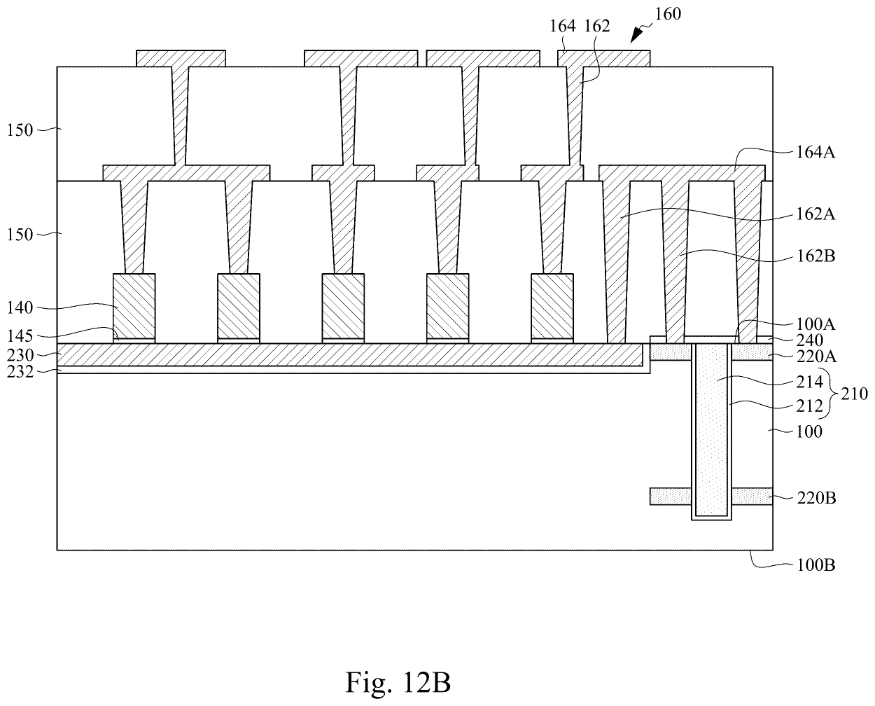

Reference is made to FIGS. 12A and 12B. An interconnect structure 160 is formed over the substrate 100. In some embodiments, multiple levels of dielectric layers may be deposited over the ILD layer 150, in which each level of the dielectric layer may include either metal vias 162 or metal lines 164, and the metal vias 162 and metal lines 164 within the dielectric layers and the ILD layer 150 are referred to as the interconnect structure 160. In some embodiments, the multiple levels of dielectric layers and the ILD layer 150 are collectively referred to as ILD layer 150. In some embodiments, forming the interconnect structure 160 includes forming a metal via 162A in contact with the top surface of the metal line 230, metal vias 162B penetrating through the dielectric cap 240 and in contact with the source/drain region 220A, and a metal line 164A in contact with the metal vias 162A and 162B.

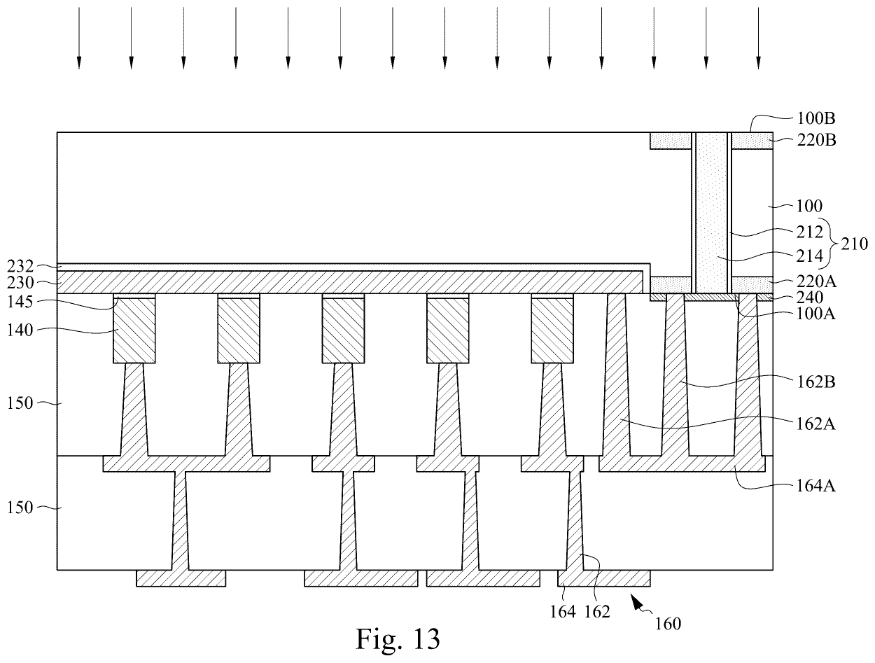

Reference is made to FIG. 13. The structure of FIGS. 12A and 12B may be flipped over by, for example, 180 degrees, such that the back side (e.g., second side 100B) of the substrate 100 faces upwardly. Then, a grinding process is performed on the second side 100B of the substrate 100 to thin down the substrate 100 until the source/drain region 220B is exposed. In some embodiments, the grinding process also remove portions of the gate structure 210 and thus the gate electrode 214 of the gate structure 210 is exposed through the second side 100B of the substrate 100.

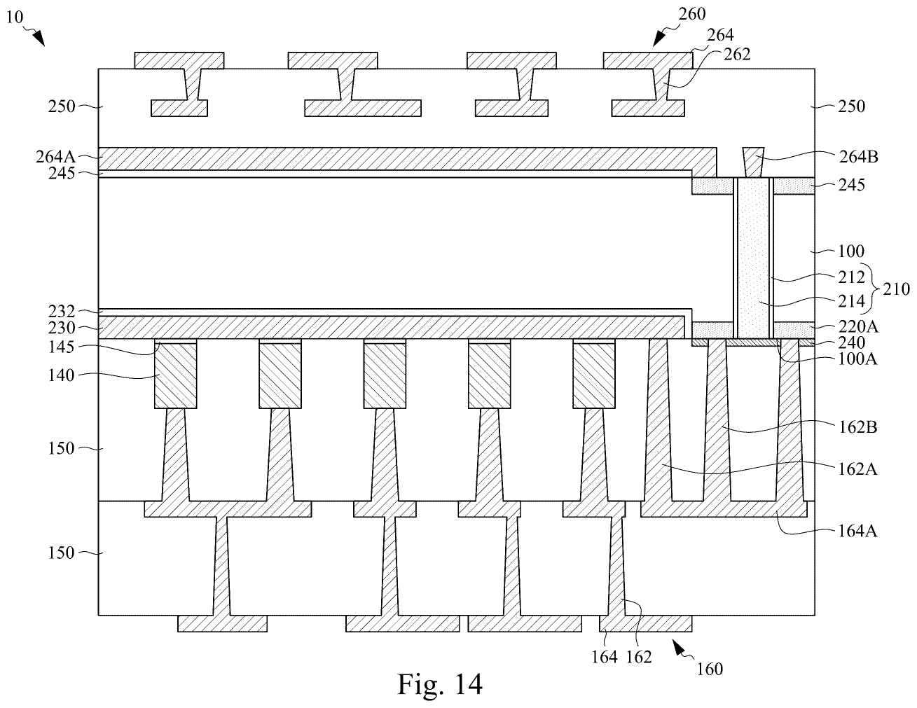

Reference is made to FIG. 14. A dielectric layer 245 is formed over the second side 100B of the substrate 100. The dielectric layer 245 may be formed by, for example, depositing a dielectric material over the second side 100B of substrate 100, and then patterning the dielectric material according to a desired pattern. In some embodiments, the source/drain region 220B and the gate structure 210 may be free of coverage by the dielectric layer 245.

An interconnect structure 260 is then formed over the second side 100B of substrate 100. In some embodiments, multiple levels of dielectric layers may be deposited over second side 100B of substrate 100, in which each level of the dielectric layer may include either metal vias 262 or metal lines 264, and the metal vias 262 and metal lines 264 within the dielectric layers are referred to as the interconnect structure 260. In some embodiments, the multiple levels of dielectric layers are collectively referred to as the dielectric layer 250. In some embodiments, forming the interconnect structure 260 includes forming a metal line 264A over the dielectric layer 245 and having a portion in contact with the source/drain region 220B, and a gate contact 264B in contact with the gate electrode 214 of the gate structure 210.

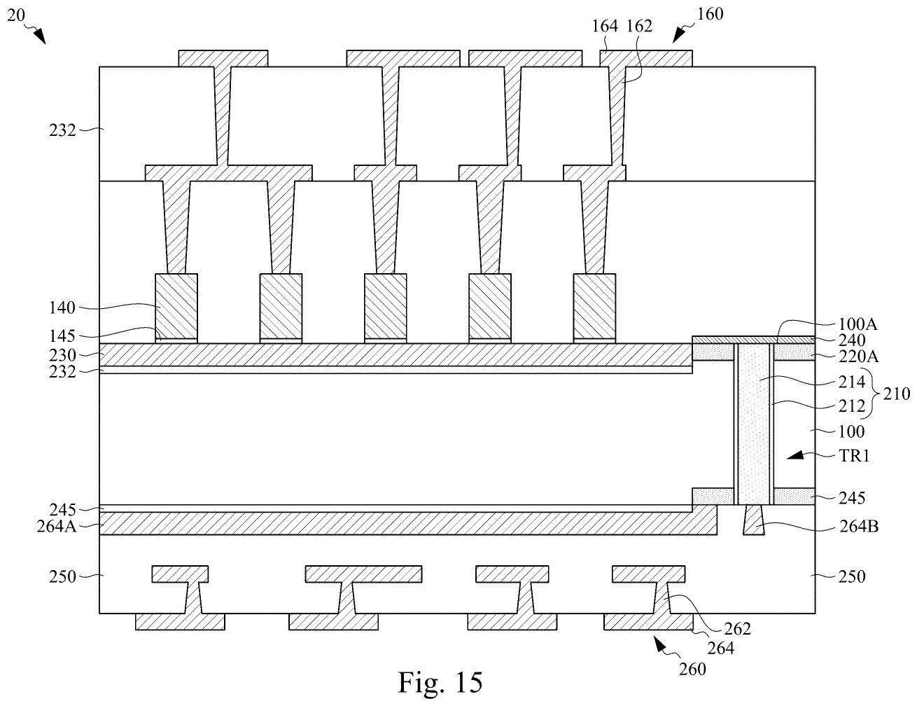

FIG. 15 is a cross-sectional view of a semiconductor device in accordance with some embodiments of the present disclosure. FIG. 15 illustrates a semiconductor device 20 that is similar to the semiconductor device 10 as described above. Accordingly, similar elements are labeled the same, and relevant details are not repeated for brevity.

In the semiconductor device 20 of FIG. 15, the metal line 230 is in contact with the source/drain region 220A of the transistor TR1. In greater detail, at least a sidewall of the metal line 230 is free of coverage by the dielectric liner 232, such that the sidewall of the metal line 230 can touch and form electrical connection with the source/drain region 220A of the transistor TR1. Such configuration can be formed by, for example, during forming the dielectric liner 232 (see FIG. 5), a patterning process or etching process may be performed to remove unwanted portion of the dielectric liner 232 to expose the sidewall of the source/drain region 220A, such that the metal line 230 can be in contact with the source/drain region 220A. In such embodiments, the metal vias 162A and 162B and the metal line 164A of FIG. 1C may be omitted.

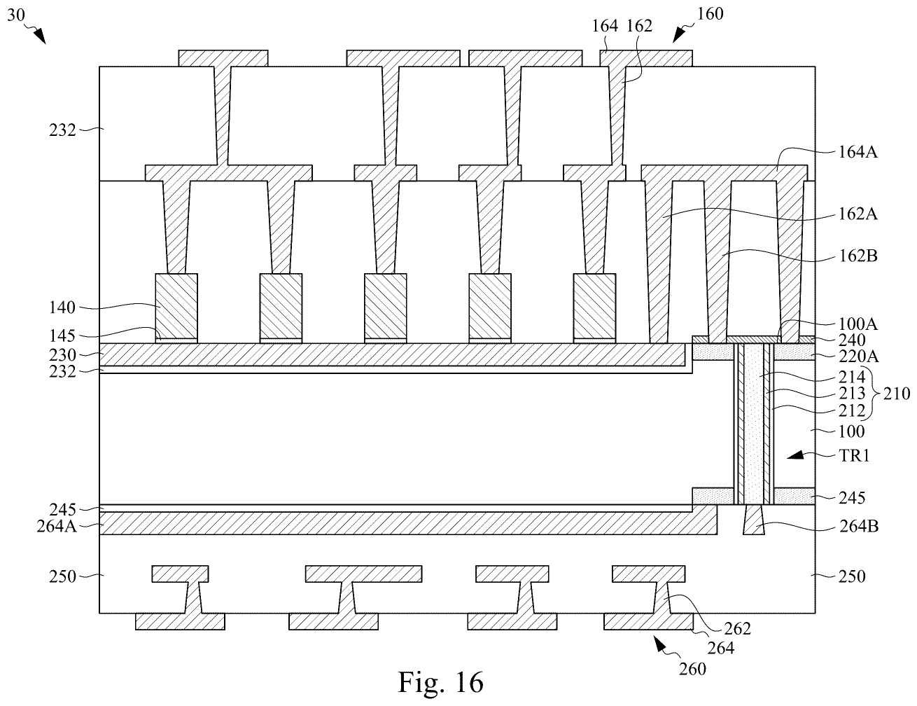

FIG. 16 is a cross-sectional view of a semiconductor device in accordance with some embodiments of the present disclosure. FIG. 16 illustrates a semiconductor device 30 that is similar to the semiconductor device 10 as described above. Accordingly, similar elements are labeled the same, and relevant details are not repeated for brevity. It is understood that the structure of FIG. 16 may also be applied to the semiconductor device 20 of FIG. 15.

In the semiconductor device 30 of FIG. 16, the gate structure 210 further includes a high-k dielectric layer 213 between the gate dielectric layer 212 and the gate electrode 214. In such embodiments, the gate dielectric layer 212 may include oxide, such as silicon oxide (SiO₂), or the like, and may also be referred to as an interfacial layer. In other embodiments, the high-k dielectric layer 213 may include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In this configuration, the top surface of the gate electrode 214, the top ends of the high-k dielectric layer 213, and the top ends of the gate dielectric layer 212 may be substantially level with the top surface of the substrate 100. Such configuration can be formed by, for example, during forming the gate structure 210 (see FIG. 4), depositing the high-k dielectric layer 213 over the gate dielectric layer 212 prior to depositing the gate electrode 214, and the resulting structure is shown in FIG. 16.

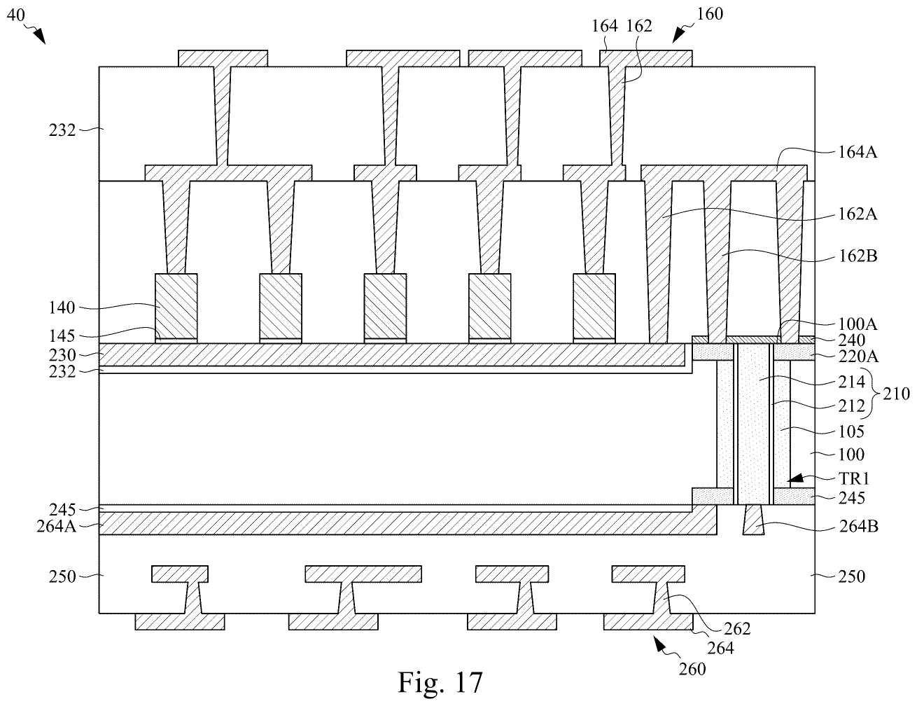

FIG. 17 is a cross-sectional view of a semiconductor device in accordance with some embodiments of the present disclosure. FIG. 17 illustrates a semiconductor device 40 that is similar to the semiconductor device 10 as described above. Accordingly, similar elements are labeled the same, and relevant details are not repeated for brevity. It is understood that the structure of FIG. 17 may also be applied to the semiconductor device 20 of FIG. 15 and the semiconductor device 30 of FIG. 16.

In the semiconductor device 40 of FIG. 17, the substrate 100 further includes an epitaxial layer 105, and the gate structure 210 may penetrate through the epitaxial layer 105. Stated another way, the epitaxial layer 105 laterally surrounds the gate structure 210, and may separate the gate structure 210 from the substrate 100. The epitaxial layer 105 may include a different semiconductor material than the substrate 100. For example, if the substrate 100 is made of silicon, the epitaxial layer 105 may include germanium (Ge), silicon germanium (SiGe), or the like. In some embodiments, the source/drain regions 220A and 220B are at opposite sides of the epitaxial layer 105, and the epitaxial layer 105 may act as a channel region of the transistor TR1. In some embodiments where the epitaxial layer 105 is a germanium-containing material, the gate dielectric layer 212 may include germanium oxide (GeO₂).

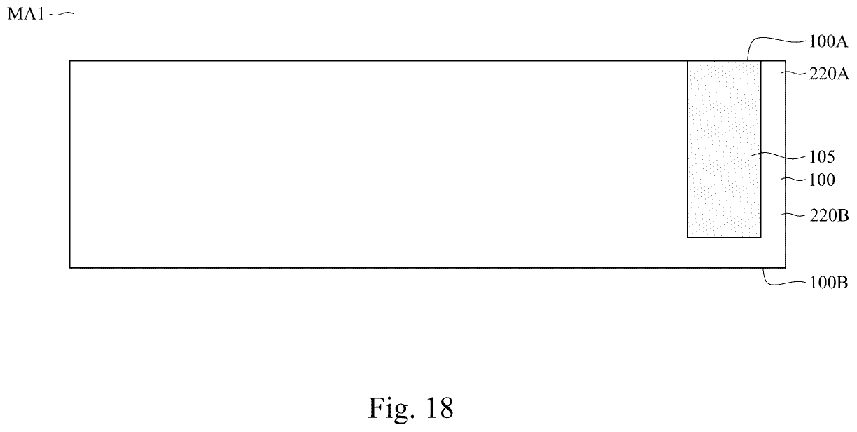

FIGS. 18 to 21 illustrate a method in various stages of forming a semiconductor device in accordance with some embodiments of the present disclosure. In greater detail, FIGS. 18 to 21 illustrate a method for forming the semiconductor device of FIG. 17. It is noted that the processes of FIGS. 18 to 21 may be similar to those above described with respect to FIGS. 2 to 14, and the relevant details are not repeated for brevity.

Reference is made to FIG. 18. An epitaxial layer 105 is formed in the substrate 100. The epitaxial layer 105 may be formed by, for example, etching the substrate 100 to form a trench, depositing a material of the epitaxial layer 105 in the trench, and then performing a planarization process to remove excess material of the epitaxial layer 105 until the top surface of the substrate 100 is substantially level with the top surface of the epitaxial layer 105.

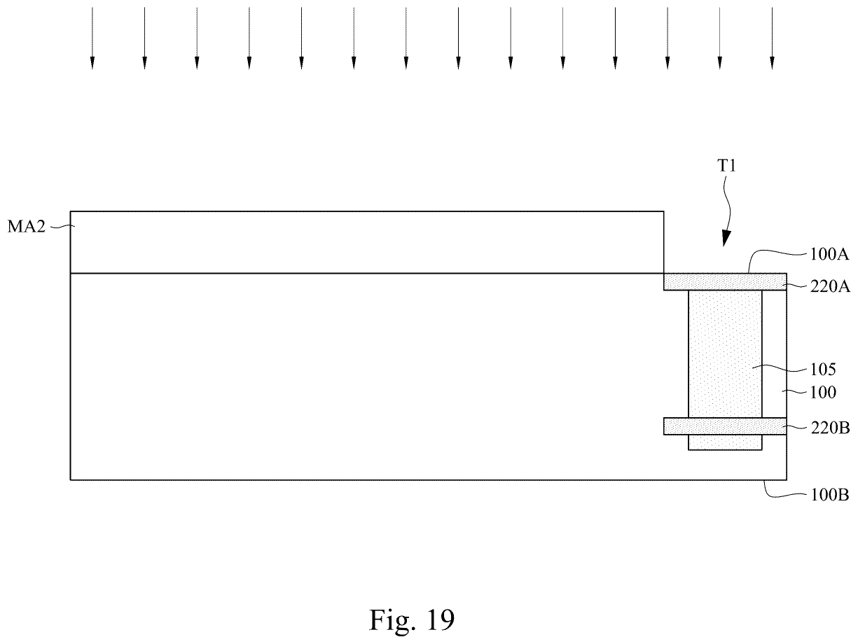

Reference is made to FIG. 19. A patterned mask MA1 is formed over the substrate 100 and having an opening exposing portions of the epitaxial layer 105 and the substrate 100. Afterwards, source/drain regions 220A and 220B are formed at different levels of the substrate 100 (and the epitaxial layer 105) through the opening of the patterned mask MA1.

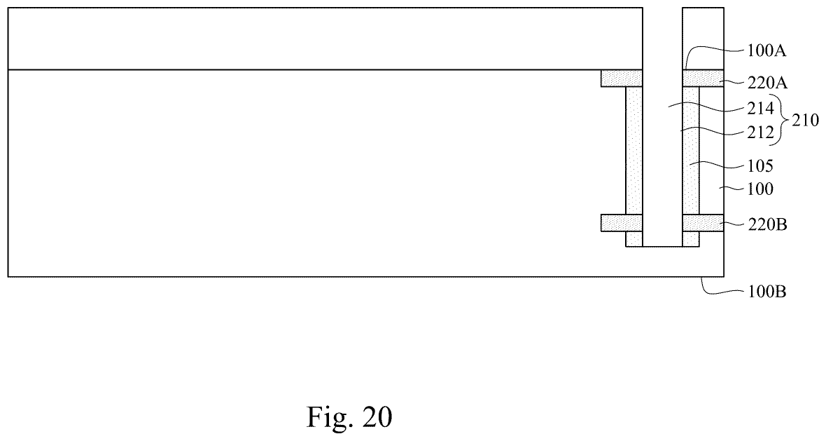

Reference is made to FIG. 20. Once the source/drain regions 220A and 220B are formed, the patterned mask MA1 is removed. Then, a patterned mask MA2 is formed over the substrate 100 and having an opening overlapping the source/drain regions 220A and 220B. Afterwards, an etching process is performed to etch the epitaxial layer 105 through the opening of the patterned mask MA2, so as to form a trench T1 in the epitaxial layer 105.

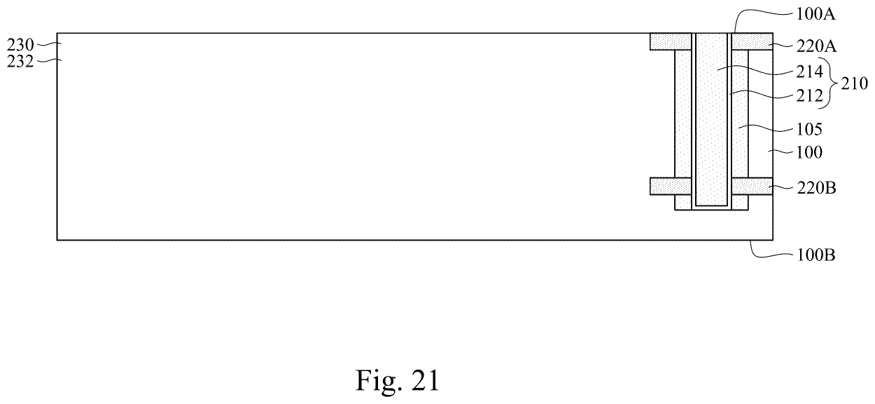

Reference is made to FIG. 21. Once the trench T1 is formed, the patterned mask MA2 is removed. Then, a gate structure 210 is formed in the trench T1 of the epitaxial layer 105. In some embodiments, the gate structure 210 may be formed by, for example, depositing a gate dielectric layer 212 lining the trench T1 in the epitaxial layer 105, depositing a gate electrode 214 over the gate dielectric layer 212 and overfilling the trench T1, followed by a planarization process, such as CMP to remove excess materials of the gate dielectric layer 212 and the gate electrode 214 until the top surface of the epitaxial layer 105 is exposed. The structure of FIG. 21 may undergo the processes as discussed in FIGS. 5 to 14, and the resulting structure is shown in FIG. 17.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a structure by utilizing the through-silicon via as a transistor. The transistor provides a way for power gating to the front-side devices without sacrificing area on the backside. A long channel and therefore high stability of the device can be achieved while avoiding a large device footprint.

In some embodiments of the present disclosure, a semiconductor device includes a substrate and a transistor in the substrate. The transistor includes a gate structure penetrating through the substrate, a first source/drain region at a front side of the substrate, and a second source/drain region at a back side of the substrate.

In some embodiments, the semiconductor device further includes a metal line in the substrate and electrically connected to the first source/drain region of the transistor.

In some embodiments, a top surface of the metal line is substantially level with a top surface of the substrate.

In some embodiments, the semiconductor device further includes a dielectric liner between the metal line and the substrate.

In some embodiments, the semiconductor device further includes a dielectric cap extending along the front side of the substrate and in contact with the gate structure and the first source/drain region of the transistor, wherein the metal line is free of coverage by the dielectric cap.

In some embodiments, the semiconductor device further includes a first via in contact with the metal line, a second via penetrating through the dielectric cap and in contact with the first source/drain region of the transistor, and a metal line electrically connecting with the first via and the second via.

In some embodiments, the semiconductor device further includes a metal line at the back side of the substrate and in contact with the second source/drain region of the transistor, and a gate contact at the back side of the substrate and in contact with the gate structure of the transistor.

In some embodiments, the semiconductor device further includes a dielectric layer between the metal line and the substrate.

In some embodiments, the semiconductor device further includes an epitaxial layer in the substrate, wherein the epitaxial layer is made of a different material than the substrate, and the gate structure penetrates through the epitaxial layer.

In some embodiments, the gate structure includes a gate electrode, a high-k dielectric layer lining the gate electrode, and an interfacial layer lining the high-k dielectric layer.

In some embodiments of the present disclosure, a semiconductor device includes a substrate, a first transistor in the substrate, and a second transistor over the substrate and at a level higher than the first transistor. The first transistor includes a gate structure, a first source/drain region adjacent to the gate structure and at a first level, and a second source/drain region adjacent to the gate structure and at a second level below the first level.

In some embodiments, the semiconductor device further includes an interlayer dielectric layer over the substrate and covering the first transistor and the second transistor, and a dielectric cap vertically between the interlayer dielectric layer and the second transistor.

In some embodiments, a top surface of the gate structure is substantially level with a top surface of the substrate, and a bottom surface of the gate structure is substantially level with a bottom surface of the substrate.

In some embodiments, the semiconductor device further includes a metal line in the substrate and electrically connected to the first transistor, wherein the metal line is vertically below a source/drain epitaxial structure of the second transistor.

In some embodiments, the semiconductor device further includes an isolation layer vertically between the metal line and the source/drain epitaxial structure of the second transistor.

In some embodiments of the present disclosure, a method includes forming a first source/drain region and a second source/drain region in a substrate, wherein the second source/drain region is at a level lower than the first source/drain region; etching the substrate to form a trench in the substrate and penetrating through the first source/drain region and the second source/drain region; and forming a gate structure in the trench.

In some embodiments, the method further includes forming a metal line in the substrate and electrically connected to the first source/drain region.

In some embodiments, the method further includes forming a dielectric cap over the substrate and covering the first source/drain region and the gate structure.

In some embodiments, the method further includes performing a grinding process on a back side of the substrate until the gate structure is exposed.

In some embodiments, the method further includes forming a metal line and a gate contact on the back side of the substrate and electrically connected to the second source/drain region and the gate structure, respectively.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
a transistor in the substrate and comprising:
a gate structure penetrating through the substrate;
a first source/drain region at a front side of the substrate; and
a second source/drain region at a back side of the substrate.

2. The semiconductor device of claim 1, further comprising a metal line in the substrate and electrically connected to the first source/drain region of the transistor.

3. The semiconductor device of claim 2, wherein a top surface of the metal line is substantially level with a top surface of the substrate.

4. The semiconductor device of claim 2, further comprising a dielectric liner between the metal line and the substrate.

5. The semiconductor device of claim 2, further comprising a dielectric cap extending along the front side of the substrate and in contact with the gate structure and the first source/drain region of the transistor, wherein the metal line is free of coverage by the dielectric cap.

6. The semiconductor device of claim 5, further comprising:
a first via in contact with the metal line;
a second via penetrating through the dielectric cap and in contact with the first source/drain region of the transistor; and
a metal line electrically connecting with the first via and the second via.

7. The semiconductor device of claim 1, further comprising:
a metal line at the back side of the substrate and in contact with the second source/drain region of the transistor; and
a gate contact at the back side of the substrate and in contact with the gate structure of the transistor.

8. The semiconductor device of claim 7, further comprising a dielectric layer between the metal line and the substrate.

9. The semiconductor device of claim 1, further comprising an epitaxial layer in the substrate, wherein the epitaxial layer is made of a different material than the substrate, and the gate structure penetrates through the epitaxial layer.

10. The semiconductor device of claim 1, wherein the gate structure comprises:
a gate electrode;
a high-k dielectric layer lining the gate electrode; and
an interfacial layer lining the high-k dielectric layer.

11. A semiconductor device, comprising:
a substrate;
a first transistor in the substrate and comprising:
a gate structure;
a first source/drain region adjacent to the gate structure and at a first level; and
a second source/drain region adjacent to the gate structure and at a second level below the first level; and
a second transistor over the substrate and at a level higher than the first transistor.

12. The semiconductor device of claim 11, further comprising:
an interlayer dielectric layer over the substrate and covering the first transistor and the second transistor; and
a dielectric cap vertically between the interlayer dielectric layer and the second transistor.

13. The semiconductor device of claim 11, wherein a top surface of the gate structure is substantially level with a top surface of the substrate, and a bottom surface of the gate structure is substantially level with a bottom surface of the substrate.

14. The semiconductor device of claim 11, further comprising a metal line in the substrate and electrically connected to the first transistor, wherein the metal line is vertically below a source/drain epitaxial structure of the second transistor.

15. The semiconductor device of claim 14, further comprising an isolation layer vertically between the metal line and the source/drain epitaxial structure of the second transistor.

16. A method, comprising:
forming a first source/drain region and a second source/drain region in a substrate, wherein the second source/drain region is at a level lower than the first source/drain region;
etching the substrate to form a trench in the substrate and penetrating through the first source/drain region and the second source/drain region; and
forming a gate structure in the trench.

17. The method of claim 16, further comprising forming a metal line in the substrate and electrically connected to the first source/drain region.

18. The method of claim 16, further comprising forming a dielectric cap over the substrate and covering the first source/drain region and the gate structure.

19. The method of claim 16, further comprising performing a grinding process on a back side of the substrate until the gate structure is exposed.

20. The method of claim 19, further comprising forming a metal line and a gate contact on the back side of the substrate and electrically connected to the second source/drain region and the gate structure, respectively.
